(19) United States
(12) Patent Application Publication
(10) Pub. No.: US 2012/0168807 A1
(43) Pub. Date: Jul. 5, 2012

(54) Tri-color LED module structure

(75) Inventors: Ching-Hao Chung, Kaohsiung City (TW); Hsiu-Chen Li, Pingtung City (TW); Pei-Tung Chung, Kaohsiung City (TW)

(73) Assignee: Forward Electronics Co., Ltd., Taipei City (TW)

(21) Appl. No.: 13/064,512

(22) Filed: Mar. 30, 2011

(30) Foreign Application Priority Data
Dec. 30, 2010 (TW) 099225582

(51) Int. Cl. H01L 33/48

(52) U.S. Cl. 257/99; 257/E33.056

(57) ABSTRACT

A tri-color LED module structure includes an insulating base, four terminals, a tri-color LED chip, and a cover. The insulating base has a receiving recess. The four terminals do not contact with one another, and each of them includes an inserting portion and a touching portion which are connected with each other. The touching portion is received in the receiving recess; while the inserting portion extends out of the insulating base. The four terminals and the insulating base are an integrally formed structure. The tri-color LED chip is disposed in the receiving recess of the insulating base, with four pins of the tri-color LED chip in touch with the touching portions of the four terminals, respectively. Further, the cover covers on the receiving chamber of the insulating base. Thereby, an independent red-green-blue tri-color LED loop can be constituted, making color mixing become possible by controlling various voltage combination.

### BACKGROUND OF THE INVENTION

1. Field of the Invention

The present invention relates to a light emitting diode (LED), and more particularly, to a tri-color LED structure adapted for modularization.

2. Description of Related Art

LEDs relate to semi-conductor components having merits in less power consumption, long life of use, and energy saving. In an era of environmental protection and energy saving, LEDs have been widely used in various lighting facilities.

Conventional LEDs, for responding demands on compact-size packaging and factory automation, adopt surface mount technique to combine LED chips and connecting terminals as LED products, so called SMD “Surface Mounted Device” LED. However, since the LED chips have a poorer heat resistance than common chips, the LEDs tend to be affected by high temperature incurred during a solder-pot manufacturing process. This will result in a malfunction phenomenon and adversely affect yield rate of the overall products, virtually making waste on manpower and time. As a result, the products have a higher cost and become less competitive.

Further, since the conventional LEDs, in order to become products, have to be assembled with the connecting terminals. This, however, makes LED products bulky and against the trend that electronic information products are getting lighter and more compact in dimension. Besides, the conventional LEDs are limited in mono-color and cannot be mixed with other LEDs for different colors. In other words, users cannot change the LEDs into other colors, and as such, the conventional LED structure is not desirable.

It is, therefore, significant to solve the problem, as mentioned above, and as such, a “tri-color LED module structure” is accomplished after research and persistent experiments.

### SUMMARY OF THE INVENTION

An object of the present invention is to provide a tri-color LED module structure by incorporating four individual terminals and a tri-color LED chip so as to constitute an independent red-green-blue tri-color LED loop, making color mixing become possible by controlling various voltage combination.

Another object of the present invention is to provide a tri-color LED module structure where the four terminals, finished by punching technique, are molding-injected together with an insulating base. Further, through a cover, the tri-color LED chip can be attached to the insulating base, without the need of a mounting measure by soldering. This will avoid the shortage of the conventional art where the surface mount manufacturing process is easily affected by high temperature. As such, according to the present invention, quality of production can be raised, and a lighter and more compact tri-color LED module structure obtained.

To achieve the objects, as mentioned above, the tri-color LED module structure, according to the present invention, comprises an insulating base, four terminals, a tri-color LED chip, and a cover. The insulating base has an upper surface, wherein the upper surface is recessed with a receiving chamber, and the receiving chamber has a receiving recess.

The four terminals include a first terminal, a second terminal, a third terminal, and a fourth terminal which do not contact with one another. The terminals each include an inserting portion and a touching portion which are connected with each other. The touching portion is received in the receiving recess of the insulating base; while the inserting portion extends out of the insulating base. The four terminals and the insulating base are an integrally formed structure.

The tri-color LED chip is disposed in the receiving recess of the insulating base, with four pins of the tri-color LED chip in touch with the touching portions of the four terminals, respectively. Further, the cover covers on the receiving chamber of the insulating base, and is provided with a through hole accommodating the tri-color LED chip.

According to the present invention, the tri-color LED chip may have at least one shoulder, where the through hole of the cover accommodates the shoulder of the tri-color LED chip, so that the cover and the tri-color LED chip can be readily engaged with each other.

According to the present invention, the inserting portions of the four terminals may be located at the same side of the insulating base, or of course, the inserting portions of the four terminals may be located at different sides of the insulating base. In addition, the insulating base may be recessed, at a side thereof, with an engaging groove so as to make the overall tri-color LED module structure engaged easily with other incorporated components.

Other objects, advantages, and novel features of the present invention will become more apparent from the following detailed description when taken in conjunction with the accompanying drawings.

### BRIEF DESCRIPTION OF THE DRAWINGS

FIG. 1 is an exploded view illustrating a tri-color LED module structure according to the present invention;

FIG. 2 is a perspective view illustrating the tri-color LED module structure according to the present invention; and

FIG. 3 is a cross-sectional view illustrating the tri-color LED module structure according to the present invention.

### DETAILED DESCRIPTION OF THE PREFERRED EMBODIMENTS

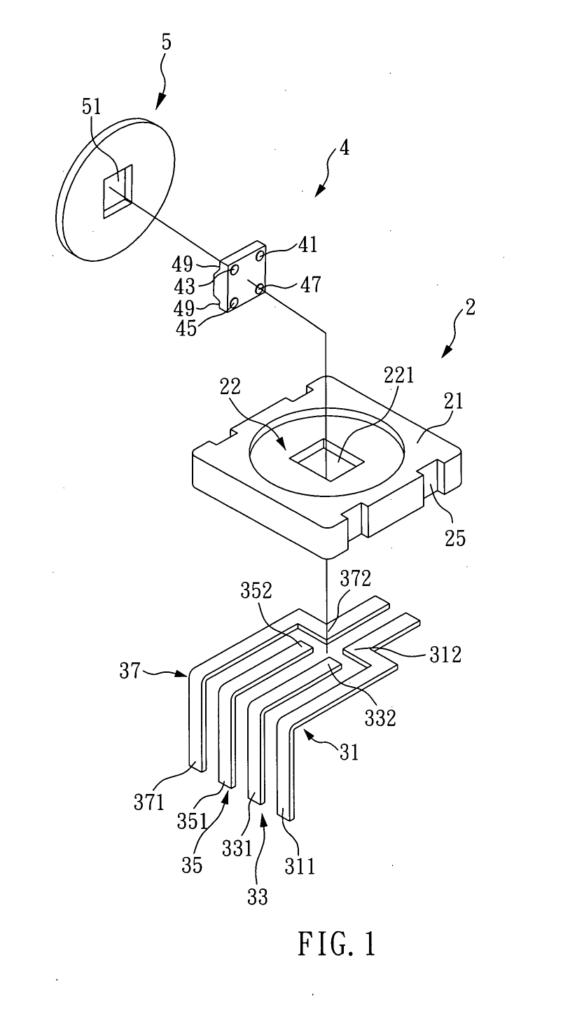

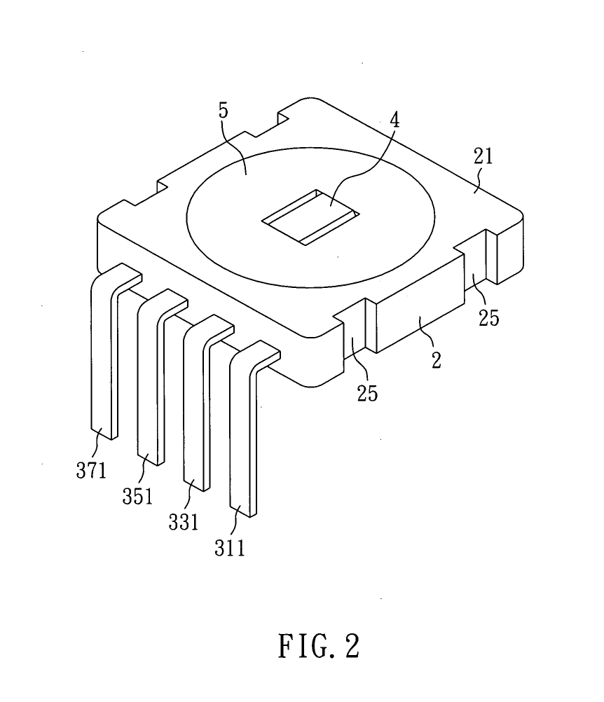

Referring to FIG. 1, an exploded view illustrating a tri-color LED module structure according to the present invention, and to FIG. 2, a perspective view illustrating the tri-color LED module structure, the tri-color LED module structure comprises an insulating base 2, four terminals 31,33,35,37, a tri-color LED chip 4, and a cover 5.

As shown in FIG. 1, the insulating base 2 has an upper surface 21, wherein the upper surface 21 is recessed with a receiving chamber 22, and the receiving chamber 22 has a receiving recess 221. According to the present invention, the receiving recess 221 is positioned centrally of the insulating base 2, where the insulating base 2 is recessed, at two corresponding sides thereof, with two engaging grooves 25 such that the engaging grooves 25 can make the overall tri-color LED module structure engaged easily with other incorporated components.

The four terminals 31,33,35,37 will not contact with one another, including a first terminal 31, a second terminal 33, a third terminal 35, and a fourth terminal 37. The terminals 31,33,35,37 each include an inserting portion 311,331,351,371 and a touching portion 312,332,352,372, which are connected with one another. The touching portions 312,332,352,372 are received in the receiving recess 221 of the insulating base 2; while the inserting portions 311,331,351,371 extend out of the insulating base 2. The four terminals 31,33,35,37 and the insulating base 2 are an integrally formed structure (see FIG. 2). In the present invention, the inserting portions 311,331,351,371 of the four terminals 31,33,35,37 are located at the same side of the insulating base 2, and that the inserting portions 311,331,351,371 of the four terminals 31,33,35,37 are each perpendicular to the insulating base 2.

The tri-color LED chip 4 is disposed in the receiving recess 221 of the insulating base 2, with four pins 41,43,45,47 of the tri-color LED chip 4 in touch with the touching portions 312,332,352,372 of the four terminals 31,33,35,37.

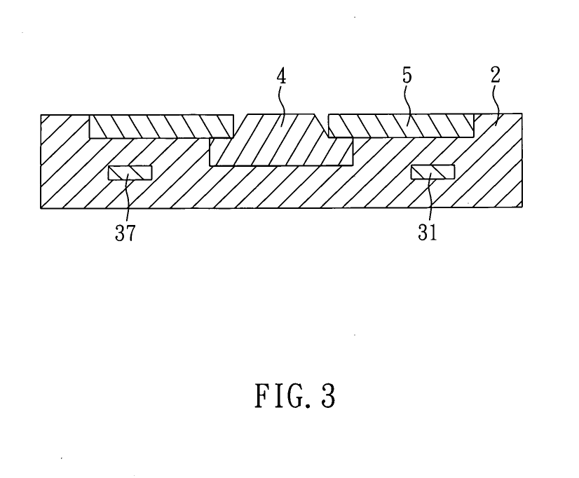

As shown in FIG. 1, the cover 5 covers on the receiving chamber 22 of the insulating base 2, and is provided with a through hole 51 where the through hole 51 accommodates two shoulders 49 of the tri-color LED chip 4. As shown in FIG. 3, a cross-sectional view illustrating the tri-color LED module structure, the cover 5 abuts on the two shoulders 49 of the tri-color LED chip 4 such that the top of the cover 5 aligns with that of the tri-color LED chip 4 after assembling of the cover 5 and the tri-color LED chip 4. Namely, the cover 5, the tri-color LED chip 4, and the insulating base 2 of the overall tri-color LED module structure align with one another.

Therefore, according to the present invention, the four individual terminals 31,33,35,37 incorporate with the tri-color LED chip 4 so as to constitute an independent red-green-blue tri-color LED loop, making color mixing become possible by controlling various voltage combination. Further, the four terminals 31,33,35,37, finished by punching technique, can be molding-injected together with the insulating base 2. Then through the cover 5, the tri-color LED chip 4 can be disposed in the receiving recess 221 of the insulating base 2, without mounting thereon by a soldering measure. This will avoid the shortage of the conventional art where the surface mount manufacturing process is easily affected by high temperature. As such, according to the present invention, quality of production can be raised, and a lighter and more compact tri-color LED module structure obtained.

Although the present invention has been explained in relation to its preferred embodiments, it is to be understood that many other possible modifications and variations can be made without departing from the scope of the invention as hereinafter claimed.

What is claimed is:

1. A tri-color LED module structure, comprising:
an insulating base, having an upper surface, wherein the upper surface is recessed with a receiving chamber, and the receiving chamber has a receiving recess;
four terminals, including a first terminal, a second terminal, a third terminal, and a fourth terminal which do not contact with one another, wherein the terminals each include an inserting portion and a touching portion which are connected with each other, and wherein the touching portion is received in the receiving recess of the insulating base, and the inserting portion extends out of the insulating base, and the four terminals and the insulating base are an integrally formed structure;
a tri-color LED chip, being disposed in the receiving recess of the insulating base, and having four pins in touch with the touching portions of the four terminals, respectively; and
a cover, covering on the receiving chamber of the insulating base, and being provided with a through hole accommodating the tri-color LED chip.

2. The tri-color LED module structure as claimed in claim 1, wherein the tri-color LED chip includes at least one shoulder such that the cover abuts on the shoulder.

3. The tri-color LED module structure as claimed in claim 1, wherein the inserting portions of the four terminals are located at the same side of the insulating base.

4. The tri-color LED module structure as claimed in claim 1, wherein the insulating base is recessed, at a side thereof, with an engaging groove.

5. The tri-color LED module structure as claimed in claim 1, wherein the inserting portion of each terminal is perpendicular to the insulating base.
